(19) United States
(12) Patent Application Publication
(10) Pub. No.: US 2024/0178023 A1
(43) Pub. Date: May 30, 2024

(54) PROCESS DETECTING UNIT, SUBSTRATE PROCESSING APPARATUS AND SUBSTRATE PROCESS MONITORING METHOD

(71) Applicant: TES CO., LTD, Yongin-si (KR)

(72) Inventors: Jong-Seok LEE, Yongin-si (KR); Seung-Min OH, Yongin-si (KR); In-Il JUNG, Yongin-si (KR)

(73) Assignee: TES CO., LTD, Yongin-si (KR)

(21) Appl. No.: 18/519,091

(22) Filed: Nov. 27, 2023

(30) Foreign Application Priority Data
Nov. 29, 2022 (KR) 10-2022-0162710

(51) Int. Cl. H01L 21/67; H01L 21/66

(52) U.S. Cl. CPC H01L 21/67253; H01L 21/6704; H01L 22/26

(57) ABSTRACT

Provided is a substrate processing apparatus, more particularly, a substrate processing apparatus for detecting a progress and end point of a process for a substrate when a process such as a drying process is performed for a substrate using a supercritical fluid.

### CROSS-REFERENCE TO RELATED APPLICATION

This application is based on and claims priority under 35 U.S.C. § 119 to Korean Patent Application No. 10-2022-0162710, filed on Nov. 29, 2022, in the Korean Intellectual Property Office, the disclosure of which is incorporated by reference herein in its entirety.

### TECHNICAL FIELD

The present disclosure relates to a process detecting unit, a substrate processing apparatus including the process detection unit, and a substrate process monitoring method using the substrate processing apparatus, and more particularly, to a process detecting unit and a substrate processing apparatus including the process detection unit, for detecting a progress and end point of a process for a substrate when a process such as a drying process is performed on the substrate using a supercritical fluid.

### BACKGROUND

Generally, when large-scale/high-density semiconductor devices such as large-scale integration (LSI) is manufactured on a surface of a semiconductor wafer, there is a need to form an ultrafine pattern on a wafer surface.

Such an ultrafine pattern may be formed by performing various processes such as exposure, development, and cleaning on a wafer coated with a resist, patterning the resist, and then etching the wafer to transfer a resist pattern on the wafer.

After such etching, the wafer is cleaned to remove dusts or a natural oxide film on the wafer surface. Cleaning processing is performed by immersing the wafer with a pattern formed on a surface thereof in a processing liquid such as a chemical solution or a rinse liquid, or by supplying the processing liquid to the wafer surface.

However, as semiconductor devices become more highly integrated, pattern collapse, in which the pattern on the resist or wafer surface collapses, occurs when the processing liquid is dried after cleaning.

As shown in FIG. 10, this pattern collapse corresponds to a phenomenon in which the patterns 11, 12, and 13 collapse in a direction toward a side in which a large amount of a processing liquid remains because capillary force for stretching the patterns 11, 12, and 13 from side to side is unbalanced if the processing liquid on the left and right sides of the patterns 11, 12, and 13 is unevenly dried when a processing liquid 10 remaining on a surface of the substrate S is dried after finishing the cleaning processing.

FIG. 10 shows a state in which drying of the processing liquid on left and right outer regions in which patterns are not formed on the upper surface of the substrate S is completed, while the processing liquid 10 remains in gaps between the patterns 11, 12, and 13. As a result, the patterns 11 and 13 on both the left and right sides collapse inward due to the capillary force received from the processing liquid 10 remaining between the patterns 11, 12, and 13.

The capillary force that causes the pattern collapse described above is due to the surface tension of the processing liquid that acts at a liquid/gas interface between the atmospheric atmosphere surrounding the substrate S after cleaning and the processing liquid remaining between the patterns.

Therefore, recently, a processing method of drying the processing liquid using a fluid in a supercritical state (hereinafter referred to as ‘supercritical fluid’) that does not form an interface between gas or liquid has attracted attention.

In a conventional drying method using only temperature control in a state diagram of pressure and temperature of FIG. 11, a gas-liquid equilibrium line is necessarily passed, and at this time, a capillary force is generated at a gas-liquid interface.

On the other hand, when a substrate is dried through a supercritical state using both temperature and pressure control of a fluid, the gas-liquid equilibrium line is not passed, and it may be possible to dry the substrate in a state essentially free of capillary force.

Referring to drying using a supercritical fluid with reference to FIG. 11, when the pressure of a liquid is raised from A to B and the temperature is then raised from B to C, the liquid is converted into a supercritical state C without passing the vapor-liquid equilibrium line. When the drying process is completed, the pressure of the supercritical fluid is lowered and the supercritical fluid is converted to gas D without passing the gas-liquid equilibrium line.

As described above, when a process such as a drying process for a substrate is performed using a supercritical fluid, pressurization and depressurization are repeated using a high-pressure fluid of approximately 10 MPa or more inside the chamber, and thus it is not easy to accurately detect a progress of the process or an end time of the process. This is because it is difficult to accurately measure the remaining amount of organic solvents such as isopropyl alcohol (IPA) on the substrate located inside a chamber.

In a conventional device, a sampling port is connected to a vent line of a fluid, the mixed fluid is sampled, the pressure is reduced, and a concentration of the IPA or particles are measured using a densitometer or particle counter, or a transmissive window is provided in the vent line to measure an internal phase change or IPA concentration in real time using a photometer.

However, real-time monitoring is difficult because sampling and analysis are performed at a certain time interval according to a technology of connecting the sampling port to the vent line, and when the transmissive window is provided in the vent line, sapphire or tempered glass is used for the transmissive window, and thus there are durability limitations due to repeated pressurization/depressurization, and high investment and maintenance costs are required for an optical system.

### SUMMARY

To overcome the above problem of the present disclosure, an object of the present disclosure is to provide a process detecting unit, a substrate processing apparatus including the process detecting unit, and a substrate process monitoring method using the substrate processing apparatus, for monitoring a progress of a process in real time and accurately detecting an end point of the process when a process such as a drying process for a substrate is performed using a supercritical fluid.

According to an aspect of the present disclosure, a substrate processing apparatus includes a chamber providing a processing space in which a process is performed on a substrate coated with a processing liquid or an organic solvent using a fluid in a supercritical state, and a process detecting unit configured to calculate at least one parameter of the fluid discharged from the chamber and detect at least one of a progress of a process and an end point of the process for the substrate.

The parameter may include a dielectric constant of the fluid.

The process detecting unit may determine that the process for the substrate is completed when a calculated value of the dielectric constant of the fluid reaches to a predetermined reference value or less.

The reference value may be determined using a predetermined margin in the dielectric constant in a state in which the fluid does not contain the processing liquid or an organic solvent.

The process detecting unit may calculate the dielectric constant of the fluid by measuring at least one of a capacitance, reflection coefficient, and resonance frequency of the fluid.

The chamber may include at least one fluid discharge line from which the fluid in the chamber is discharged, and the process detecting unit may be provided in a section in which the fluid in the fluid discharge line is maintained in a supercritical state.

For example, the chamber may include at least one fluid discharge line from which the fluid in the chamber is discharged, a check valve provided on the fluid discharge line, and a pressure control valve provided behind the check valve on the fluid discharge line and configured to control a pressure inside the chamber, and the process detecting unit may be provided in front of the pressure control valve on the fluid discharge line.

The process detecting unit may be provided between the check valve and the pressure control valve on the fluid discharge line.

The process detecting unit may include a sensor located in the fluid discharge line, and a calculator configured to calculate a dielectric constant of the fluid with a measurement value transmitted from the sensor, and the sensor may include an external electrode providing a flow channel in which the fluid flows and an internal electrode provided inside the flow channel, and measure electric capacity of the fluid flowing between the external electrode and the internal electrode.

According to another aspect of the present disclosure, provided is a substrate process monitoring method for detecting at least one of a progress and end point of the process for a substrate coated with a processing liquid or an organic solvent in a chamber using a fluid in a supercritical state, the method including calculating at least one parameter of the fluid discharged from the chamber, and determining at least one of the progress of the process and the end point of the process for the substrate using the calculated parameter, wherein the calculating of the parameter may include calculating a dielectric constant of the fluid discharged from the chamber.

The calculating of the parameter may include calculating the dielectric constant of the fluid by measuring at least one of a capacitance, reflection coefficient, and resonance frequency of the fluid in a section in which the fluid discharged from the chamber is maintained in a supercritical state.

The determining of at least one of the progress and end point of the process may include determining that the process for the substrate is completed when a calculated value of the dielectric constant of the fluid reaches to a predetermined reference value or less.

According to an aspect of the present disclosure, a process detecting unit for detecting at least one of a progress and end point of a process for a substrate coated with a processing liquid or an organic solvent in a chamber using a supercritical state is provided, the process detecting unit including an external electrode providing a flow channel in which the fluid flows/and an internal electrode provided inside the flow channel and calculator calculating a dielectric constant of the fluid discharged from the chamber and determines at least one of a progress of a process and an end point of the process for the substrate based on a calculated parameter of the dielectric constant of the fluid, wherein the process detecting unit is provided in a section in which the fluid discharged from the chamber is maintained in a supercritical state.

The process for the substrate may be determined to be completed when the calculated value of the dielectric constant of the fluid reaches to a predetermined reference value or less.

The dielectric constant of the fluid may be calculated by measuring at least one of a capacitance, reflection coefficient, and resonance frequency of the fluid.

### BRIEF DESCRIPTION OF THE DRAWINGS

Embodiments will be more clearly understood from the following detailed description taken in conjunction with the accompanying drawings in which:

FIG. 1 is a block diagram illustrating the configuration of a substrate processing apparatus according to an embodiment of the present disclosure;

FIG. 2 is a side cross-sectional view showing the configuration of a chamber according to an embodiment of the present disclosure;

FIG. 3 is a graph showing a change in dielectric constant of carbon dioxide (CO₂) according to pressure and temperature;

FIG. 4 is a graph showing a change in dielectric constant of CO₂ according to pressure of pure CO₂ and CO₂ including a polar organic solvent;

FIGS. 5A and 5B are diagrams showing a process detection unit according to an embodiment of the present disclosure;

FIG. 6 is a graph showing a dielectric constant detected by a process detecting unit depending on a pressure change of a process processing process and a change in an organic solvent remaining in a fluid;

FIGS. 7 to 9 are diagrams showing driving of a valve in a substrate processing apparatus according to a substrate processing process;

FIG. 10 is a schematic diagram showing a state in which a pattern collapses when a pattern on a substrate is dried according to the related art; and

FIG. 11 is a state diagram showing a change in pressure and temperature of a fluid in a processing process using a supercritical fluid.

### DETAILED DESCRIPTION OF THE EMBODIMENTS

Hereinafter, the configuration of a substrate processing apparatus according to an embodiment of the present disclosure will be described in detail.

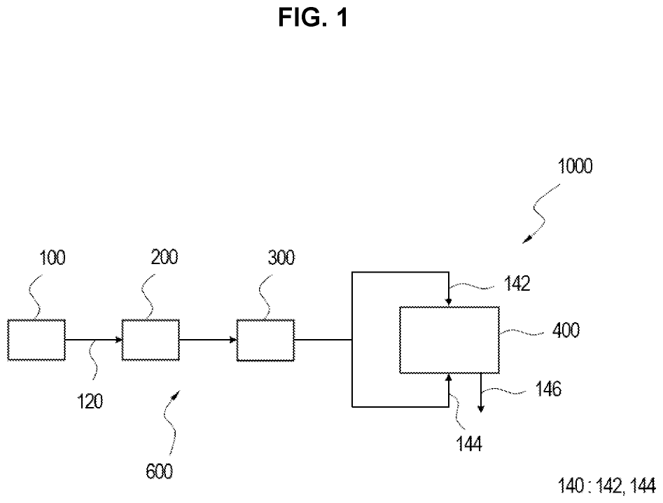

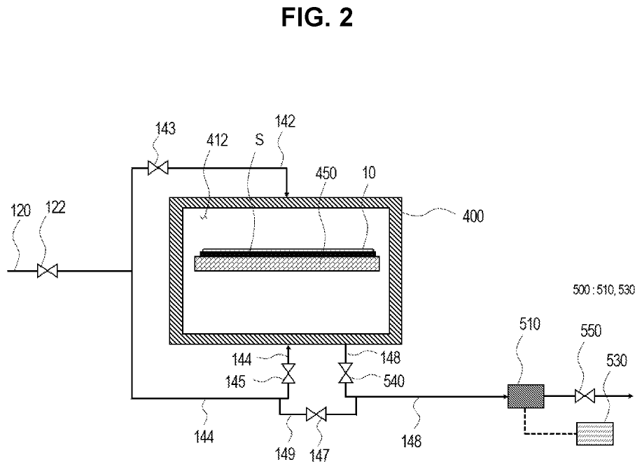

FIG. 1 is a block diagram illustrating the configuration of a substrate processing apparatus 1000 according to an embodiment of the present disclosure. FIG. 2 is a side cross-sectional view showing the configuration of a chamber 400.

The substrate processing apparatus 1000 according to the present disclosure performs a processing process for a substrate S using a supercritical fluid. Here, the supercritical fluid corresponds to a fluid having a phase formed when a material reaches a critical state, that is, a state that exceeds a critical temperature and a critical pressure. The supercritical fluid has a property with a molecular density close to liquid and a viscosity close to gas. Therefore, because the supercritical fluid is advantageous for chemical reactions because of excellent diffusion force, permeability force and dissolution ability and has little surface tension, the supercritical fluid may not apply surface tension to a microstructure, and thus may have excellent dry efficiency during a drying process of a semiconductor device and may avoid pattern collapse to be used very useful.

In the present disclosure, carbon dioxide (CO₂) may be used as a supercritical fluid. CO₂ has a critical temperature of about 31.1° C. and a relatively low critical pressure of about 7.38 MPa, and thus it is advantageous that CO₂ is easily made to a supercritical state, the state thereof is controlled by adjusting the temperature and the pressure, and CO₂ is cheap.

CO₂ is not toxic, and thus is harmless to the human body and is non-combustible and inert. Because CO₂ in a supercritical state has a diffusion coefficient that is about 10 to about 100 times higher than that of water or other organic solvents, CO₂ in a supercritical state has excellent permeability, allows rapid replacement of organic solvents, and has almost no surface tension, and thus has properties advantageous for use in a drying process. It may be possible to convert CO₂ used in the drying process into a liquid state and separate and reuse organic solvents, which has less burden in terms of environmental pollution.

Referring to FIGS. 1 and 2, the substrate processing apparatus 1000 may include the chamber 400 providing a processing space 412 in which a processing process is performed on the substrate S coated with a processing liquid or an organic solvent 10 (hereinafter referred to as ‘organic solvent’) using a supercritical fluid, and a fluid supply 600 configured to supply a liquid into the chamber 400.

The fluid supply 600 may adjust at least one of the temperature and pressure of a fluid and supply the fluid to the chamber 400 through a fluid supply line 140.

For example, the fluid supply 600 may include a fluid storage 100 configured to store the fluid and a main supply line 120 connecting the fluid storage 100 and the fluid supply line 140.

In this case, a pressure adjuster 200 and a temperature adjuster 300 may be disposed along the main supply line 120. In this case, the pressure adjuster 200 may be configured as, for example, a pressure pump, and the temperature adjuster 300 may include a heater or a heat exchanger for heating the fluid.

The main supply line 120 may further include a detector (not shown) configured to detect at least one of the pressure and temperature of the fluid. The pressure and temperature of the fluid flowing along the main supply line 120 may be adjusted according to the pressure and temperature detected by the detector. To this end, the substrate processing apparatus 1000 according to an embodiment of the present disclosure may include a controller (not shown) configured to control the pressure adjuster 200 and the temperature adjuster 300. The controller may control the pressure adjuster 200 and the temperature adjuster 300 based on the pressure and temperature detected by the detector.

When the process is performed on the substrate S, an internal environment of the processing space 412 of the chamber 400, that is, the temperature and pressure of the processing space 412 needs to be created as an environment above the critical temperature and critical pressure at which a fluid supplied to the chamber 400 is convertible into a supercritical state and maintained during the current process.

To this end, while the fluid is moved along the main supply line 120, the pressure adjuster 200 may pressurize the fluid at the critical pressure or more and also the temperature adjuster 300 may heat the fluid at the critical temperature or more.

The fluid supply line 140 may include an upper supply line 142 connected to an upper portion of the chamber 400 and a lower supply line 144 connected to a lower portion of the chamber 400.

For example, the main supply line 120 described above may be branched and the branched lines may be connected to the upper supply line 142 and the lower supply line 144, respectively. In this case, a main supply valve 122 may be provided on the main supply line 120, and an upper supply valve 143 and a lower supply valve 145 may be provided on the upper supply line 142 and the lower supply line 144, respectively, to adjust supply of the fluid.

When the fluid is supplied at the beginning of the process through an upper portion of the chamber 400, a high-pressure fluid may be supplied to the substrate S from the upper portion of the chamber 400. In this case, a pattern (not shown) formed on the substrate S may be damaged by a high-pressure fluid.

Therefore, at the beginning of the process, the fluid is supplied from a lower portion of the chamber 400 through the lower supply line 144 to prevent damage to the pattern on the substrate S. When the fluid is accommodated inside the chamber 400 and the substrate S is immersed by the fluid, for example, the fluid may be supplied from the upper portion of the chamber 400 through the upper supply line 142.

The chamber 400 include at least one fluid discharge line 148 for discharging the fluid of the processing space 412 to the outside. When a process for the substrate S is currently performed or is completed, the fluid may be discharged from the inside of the chamber 400 to the outside through the fluid discharge line 148.

The substrate processing apparatus 1000 may further include an intermediate line 149 connecting the lower supply line 144 and the fluid discharge line 148. An intermediate valve 147 including a check valve may be provided on the intermediate line 149.

When the fluid is not discharged through the fluid discharge line 148 in the operation of supplying the fluid into the chamber 400 and pressurizing the fluid, a pressure difference between the chamber 400 and the fluid discharge line 148 is increased. In this state, when the fluid is discharged from the chamber 400 through the fluid discharge line 148 in a subsequent process, a flow of the fluid may not be smooth and rapid fluctuations may occur due to a significant pressure difference between the inside of the chamber 400 and the fluid discharge line 148.

Therefore, in the operation of pressurizing the chamber 400, the fluid is discharged to the fluid discharge line 148 by the intermediate line 149 and the intermediate valve 147 to maintain a pressure of the fluid discharge line 148 at a certain level or more.

The chamber 400 may provide the processing space 412 in which a process such as a drying process is performed on the substrate S using the supercritical fluid.

The chamber 400 may be formed with an opening (not shown) at one side and may be made of a material suitable for processing a high-pressure process for the substrate S inside the chamber 400.

The processing space 412 of the chamber 400 may be maintained in a sealed state, and a pressure of the fluid supplied to the processing space 412 may be maintained at a critical pressure or more.

The chamber 400 may further include a heater (not shown) to maintain the temperature of the processing space 412 at a certain temperature or more. In the process of the substrate S by the heater, the temperature of the processing space 412 or the temperature of the fluid accommodated in the processing space 412 may be maintained above the critical temperature.

The chamber 400 may include a substrate support 450 supporting the substrate S.

In this case, the substrate support 450 may be inserted into the processing space 412 of the chamber 400 through the opening of the chamber 400, or may be ejected from the chamber 400 from the processing space 412 through the opening.

When a process such as a drying process for the substrate is performed using a supercritical fluid, pressurization and depressurization are repeated using a high-pressure fluid of about 10 MPa or more in the chamber, and thus it is not easy to accurately detect a progress of the process or an end point of the process. This is because it is difficult to accurately measure the remaining amount of an organic solvent such as isopropyl alcohol (IPA) on the substrate located inside the chamber 400.

In a conventional device, a sampling port is connected to a vent line of a fluid to sample a mixed fluid and then the pressure is reduced to measure an IPA concentration or particles using a densitometer or a particle counter, or a transmissive window is provided on a vent line to measure an internal phase change or an IPA concentration in real time using a photometer.

However, sampling and analysis are performed at a certain time interval according to a technology that connects the sampling port to the vent line, and thus real-time monitoring is difficult, and when a transmissive window is provided in the vent line, sapphire or tempered glass is used, and thus there is a constraint in terms of durability due to repeated pressurization/depressurization, and an optical system requires high investment and maintenance costs.

In the present disclosure, to resolve the above problems, provided may be a process detecting unit 500 configured to calculate at least one parameter of the fluid discharged from the chamber 400 to detect at least one of a progress of the process or an end point of the process for the substrate S.

In this case, the process detecting unit 500 may calculate a dielectric constant of the fluid discharged from the chamber 400 to determine the progress of the process according to a change of a calculation value of a dielectric constant of the fluid or determine that the process for the substrate S is terminated when the calculation value of the dielectric constant of the fluid reaches a predetermined reference value or less.

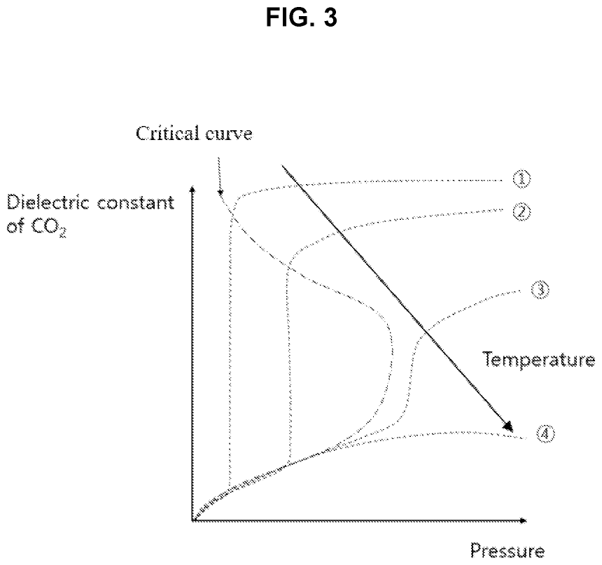

FIG. 3 is a graph showing a change in dielectric constant of CO₂ according to pressure and temperature. In FIG. 3, a horizontal axis shows pressure, and a vertical axis shows a dielectric constant.

As shown in FIG. 3, referring to curves \textcircled{1} or \textcircled{2} in which the temperature of CO₂ is lower than a critical temperature, the dielectric constant rises excessively dramatically below a critical point and the range of change in dielectric constant according to pressure beyond the critical point is very small, and thus it is difficult to detect change in the dielectric constant of CO₂ in this temperature range.

In contrast, referring to curve \textcircled{3} in which temperature approximately belongs to the range of a saturation temperature, it is easy to detect the change in dielectric constant of CO₂ because a change width in dielectric constant according to pressure beyond the critical point is relatively large as the pressure rises.

When the temperature is excessively higher than the saturated temperature, the change width in the dielectric constant according to pressure is reduced again as shown in curve \textcircled{4}, and thus it is difficult to detect the change in dielectric constant of CO₂.

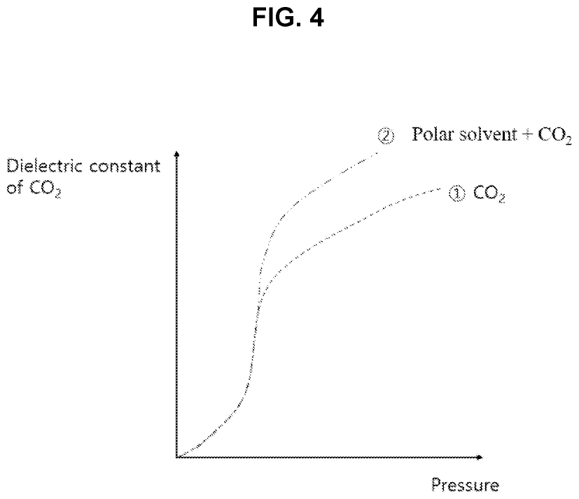

FIG. 4 is a graph showing a change in dielectric constant of CO₂ according to pressure of pure CO₂ (curve \textcircled{1}) and CO₂ (curve \textcircled{2}) including a polar organic solvent such as IPA.

As seen from FIG. 4, the change width in dielectric constant of CO₂ is greater in the case of the polar organic solvent (curve \textcircled{2}) than in the case of pure CO₂ (curve \textcircled{1}).

As a result, as seen from the graph of FIG. 3, when CO₂ is heated to an approximately saturation temperature range or the saturation temperature or more, the change in dielectric constant of CO₂ may be detected according to pressure. As seen from the graph of FIG. 4, when CO₂ contains a polar organic solvent such as IPA, the change width in the dielectric constant of CO₂ may be further increased, and thus the change width in dielectric constant may be increased according to a change in the amount of CO₂ including the remaining organic solvent, that is, a concentration of the organic solvent contained in CO₂.

Therefore, when the drying process is performed using a supercritical fluid such as CO₂ for the substrate S coated with a polar organic solvent such as IPA, it may be possible to detect the dielectric constant, which is changed according to the remaining amount of the organic solvent contained in CO₂, to determine an end point of the drying process for the substrate S.

Based on the above description given with reference to FIGS. 3 and 4, the process detecting unit 500 described above may calculate a dielectric constant of the fluid discharged from the chamber 400 to determine at least one of a progress of the process or an end point of the process for the substrate S using a supercritical fluid in the drying process.

In this case, the aforementioned reference value may be determined using a predetermined margin in a dielectric constant in a state in which a processing liquid or an organic solvent is not included in the fluid.

For example, referring to FIG. 2, the chamber 400 may include at least one fluid discharge line 148 from which the fluid inside the chamber 400 is discharged, and the fluid inside the chamber 400 is discharged through the fluid discharge line 148.

The fluid discharge line 148 may include a first valve 540 and a second valve 550. In this case, the first valve 540 may include an on/off value or a check valve, and the second valve 550 may be provided behind the first valve 540 on the fluid discharge line and may include a pressure control valve configured to control pressure inside the chamber 400. In this case, the intermediate line 149 described above may be connected to behind the first valve 540 on the fluid discharge line.

The process detecting unit 500 described above may be provided in a section in which the fluid is maintained in a supercritical state in the fluid discharge line 148.

That is, at least one of a progress of the process or an end point of the process may be more accurately detected by monitoring the supercritical state of the fluid discharge line 148 having a condition that is almost similar to the process temperature and pressure conditions of the supercritical state inside the chamber 400.

For example, the process detecting unit 500 may be provided in the fluid discharge line 148 in front of the second valve 550, that is, in front of the pressure control valve.

In the fluid discharge line 148 behind the second valve 550, a pressure drop occurs, and thus it is difficult to maintain a supercritical fluid inside the fluid discharge line 148 behind the second valve 550. Accordingly, the process detecting unit 500 may be positioned in front of the second valve 550 in the fluid discharge line 148.

The fluid may flow in a reverse direction rather than a discharge direction in the fluid discharge line 148 by the process detecting unit 500, and thus the first valve 540, that is, a check valve may be located in front of the process detecting unit 500.

As a result, the process detecting unit 500 may be located between the first valve 540 and the second valve 550 described in the fluid discharge line 148, and more specifically, may be located between the check valve and the pressure control valve.

As a result, the process detecting unit 500 may monitor the supercritical fluid on the fluid discharge line 148 in real time, and furthermore, the fluid may be prevented from being reversed.

The process detecting unit 500 may measure at least one of capacitance, reflection coefficient, and resonance frequency of the fluid to calculate the dielectric constant of the fluid.

To this end, the process detecting unit 500 may include a sensor 510 disposed in the fluid discharge line 148 and a calculator 530 configured to calculate a dielectric constant of the fluid with a measurement value transmitted from the sensor 510. According to the present embodiment, the sensor 510 and the calculator 530 are shown to be configured separately, but are not limited thereto. For example, the sensor 510 and the calculator 530 may be integrated into one, and the above-described controller may function as a calculator.

The sensor 510 is located between the check valve and the pressure control valve on the fluid discharge line 148 to measure at least one of capacitance, reflection coefficient, and resonance frequency of the fluid.

For example, according to the present embodiment, the sensor 510 may include a sensor configured to measure the electric capacity of the fluid.

That is, the electric capacity of the supercritical fluid passing through the fluid discharge line 148 may be measured by the sensor 510, and a dielectric constant of the fluid may be calculated by the measured electric capacity value.

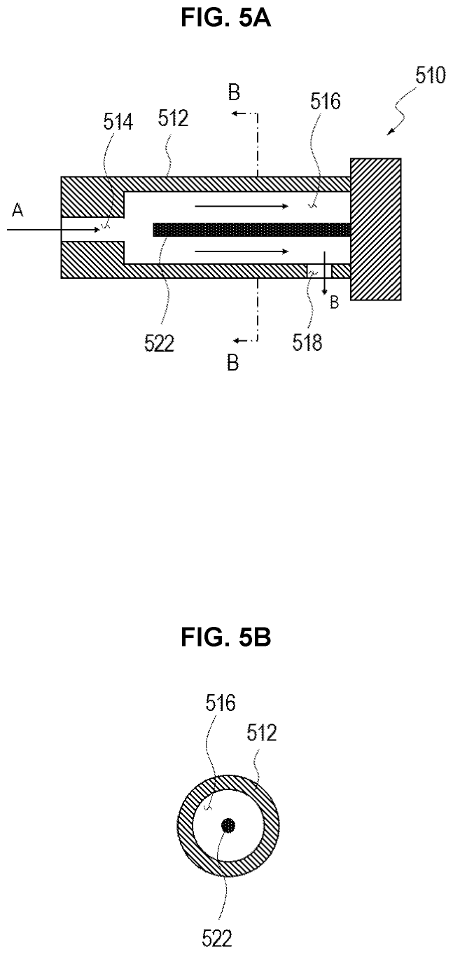

FIGS. 5A and 5B are diagrams showing the configuration of the sensor 510 described above. FIG. 5A is a side cross-sectional view of the sensor 510, and FIG. 5B is a cross-sectional view taken along line B-B in FIG. 5A.

Referring to FIGS. 5A and 5B, the sensor 510 may include an external electrode 512 providing a flow channel 516 in which the fluid flows, and an internal electrode 522 disposed inside the flow channel 516.

The external electrode 512 is shown in a circular pillar shape, but is not limited thereto, and may be any shape that may provide a flow channel of fluid therein.

An inlet 514 in which the fluid is introduced may be formed at one end of the external electrode 512, and an outlet 518 in which the fluid is discharged may be formed at the other end of the outer electrode 512.

In this case, the inlet 514 is formed on a concentric circle with the external electrode 512, and the outlet 518 is shown to be formed in a circumference direction of the external electrode 512, but is not limited thereto. That is, when the flow channel 516 through which the fluid flows may be formed between the inlet 514 and the outlet 518, the locations of the inlet 514 and the outlet 518 may not be particularly limited.

The inner electrode 522 may be disposed at an inner side of the outer electrode 512, that is, on the flow path 516. Therefore, the flow channel 516 in which the fluid flows may be formed between the internal electrode 522 and the external electrode 512.

In this case, the sensor 510 measures the electric capacity of the fluid flowing between the external electrode 512 and the internal electrode 522.

The dielectric constant of the fluid may be calculated with the measured electrostatic capacity value to determine at least one of a progress of the process or an end point of the process inside the chamber 400. Hereinafter, this will be described in detail.

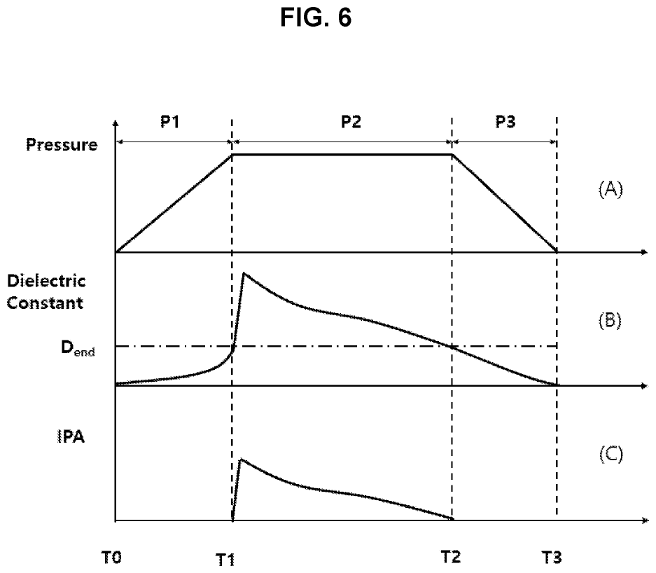

FIG. 6 is a graph of a pressure change (A) in the chamber 400 in the process for the substrate S, the dielectric constant (B) of the fluid, calculated by the process detecting unit 500, and the remaining amount (C) of an organic solvent remaining in the fluid according to the calculated dielectric constant. In FIG. 6, the horizontal axis is a time for the process.

Referring to FIG. 6, the process for the substrate S may be started to perform a pressurizing operation (P1: T0 to T1) in which the pressure inside the chamber 400 increases.

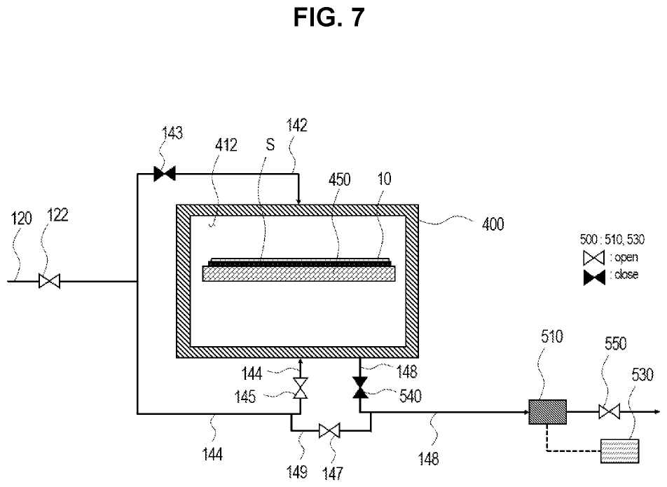

In the pressurizing operation, the aforementioned main supply valve 122 may be opened to supply a fluid into the chamber 400, as shown in FIG. 7. For example, the upper supply valve 143 is closed and the lower supply valve 145 is opened to supply a fluid to a lower portion of the chamber 400. In this case, the first valve (check valve) 540 is closed to prevent the fluid from being discharged inside the chamber 400.

In the pressurizing operation, the intermediate valve 147 is opened and the fluid is supplied to the fluid discharge line 148 through the intermediate line 149 and discharged. Therefore, even in the pressurizing operation, the dielectric constant of the fluid may be calculated through the process detecting unit 500.

However, in the pressurizing operation, the fluid discharged through the fluid discharge line 148 corresponds to a pure fluid that does not contain an organic solvent supplied through the lower supply line 144, and thus as shown in 6C, the amount of IPA remaining in the fluid corresponds to ‘0’.

As the pressure inside the chamber 400 rises in the pressurizing operation, the pressure and temperature of the fluid discharged through the fluid discharge line 148 may increase, and the dielectric constant calculated in the process detecting unit 500 may increase.

When the pressure inside the chamber 400 reaches a predetermined process pressure, a pressure maintenance operation (or isobaric process) P2 may be subsequent to the pressurizing operation P1. In the pressure maintenance operation P2, while the fluid is constantly supplied into the chamber 400, the fluid is discharged to the outside of the chamber 400 by as much as the amount of the supplied fluid, and the pressure inside the chamber 400 is maintained constant.

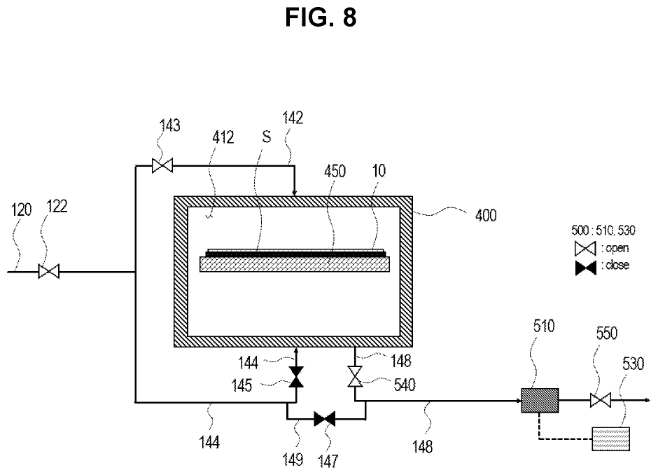

For example, as shown in FIG. 8, the upper supply valve 143 is opened while the main supply valve 122 described above is opened, and the lower supply valve 145 is closed to supply the fluid from the upper portion of the chamber 400.

The first valve (check valve) 540 is opened to discharge the fluid through the fluid discharge line 148 in the chamber 400. In this case, in the aforementioned pressurizing operation, the fluid may be continuously discharged through the fluid discharge line 148 and a pressure difference between the chamber 400 and the fluid discharge line 148 is reduced to ‘0’ or as much as possible, and thus the fluid may be discharged smoothly from the chamber 400.

In the pressure maintenance operation P2, the intermediate valve 147 described above is closed and the fluid does not flow through the intermediate line 149. This is because, when the fluid is discharged to the fluid discharge line 148 via the intermediate line 149, a pure fluid without IPA is supplied to the fluid discharge line 148, and thus it is not possible to accurately detect the amount of remaining IPA in the fluid discharged from the chamber 400.

In the pressure maintenance operation P2, the fluid containing IPA is discharged through the fluid discharge line 148, and thus the dielectric constant of the fluid, calculated by the process detecting unit 500, rapidly increases. The amount of IPA remaining in the fluid converted according to the dielectric constant of the fluid may also increase rapidly.

The amount of IPA remaining in the fluid corresponding to the dielectric constant of the fluid may be stored in the aforementioned controller or the calculator 530. For example, the amount of IPA remaining in the fluid corresponding to the dielectric constant of the fluid may be stored in a data form such as a table.

Subsequently, as the pressure maintenance operation P2 continues, the fluid containing IPA is continuously discharged from the chamber 400. Accordingly, the dielectric constant of the fluid, calculated by the process detection unit 500, may be continuously reduced, and similarly, the amount of IPA remaining in the fluid may be continuously reduced.

In the pressure maintenance operation P2, the fluid containing the organic solvent inside the chamber 400 is discharged to the outside of the chamber 400, and thus when the dielectric constant of the fluid, calculated by the process detecting unit 500, is reached to a preset reference value D_{end} or falls below the reference value D_{end}, it may be determined that the process for the substrate S is completed.

In this case, the reference value D_{end} may be determined adding a predetermined margin to a dielectric constant in a state in which the fluid does not contain the processing liquid or organic solvent 10.

Subsequent to the pressure maintenance operation described above, a depressurization operation P3 is performed. In the depressurization operation P3, the pressure inside the chamber 400 is reduced by discharging a fluid to the outside of the chamber 400 rather than supplying a fluid into the chamber 400.

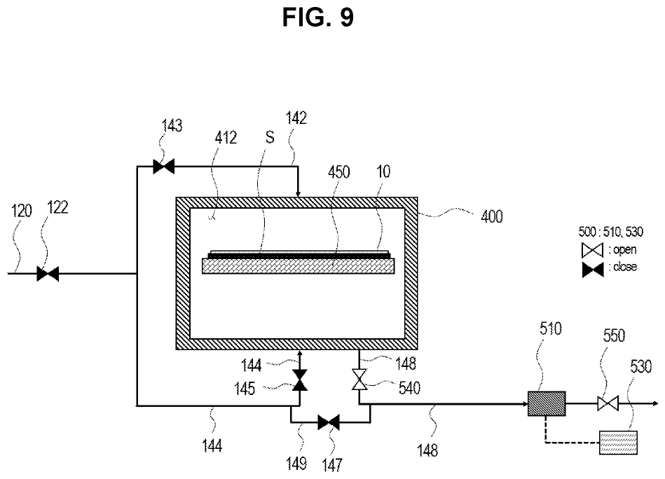

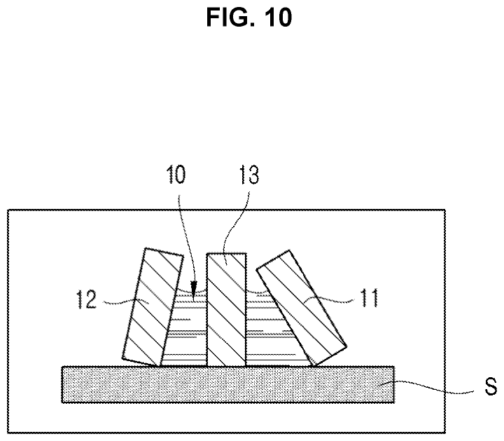

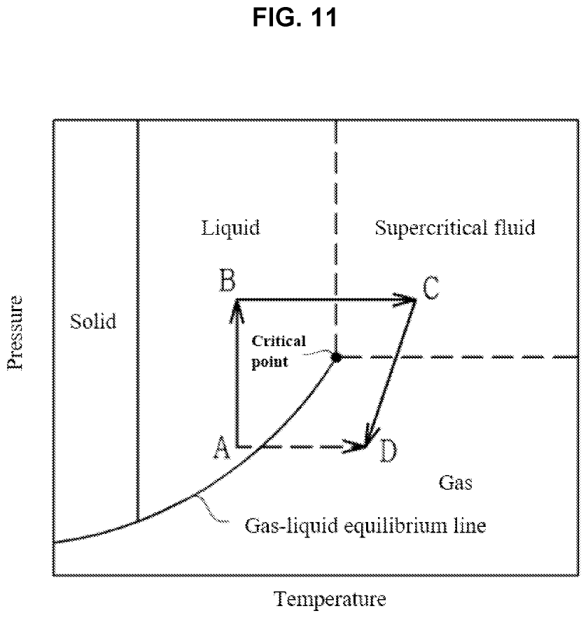

For example, as shown in FIG. 9, the above-described main supply valve 122, upper supply valve 143, lower supply valve 145, and intermediate valve 149 are closed, and the first valve 540 is opened to discharge a fluid from the chamber 400.

In the depressurization operation P3, the pressure and/or temperature of the fluid decrease, and thus the dielectric constant value calculated by the process detecting unit 500 may continue to decrease.

In the depressurization operation P3, the current state corresponds to a state in which the process for the substrate S is completed, and the amount of IPA remaining in the fluid corresponds to ‘0’.

A change value in the dielectric constant of the fluid according to a pressure change in the process for the substrate S described above may be stored in advance in the above-described controller or calculator 530 or the like. The reference value D_{end} of the fluid, for determining whether a process for the substrate S is completed, may also be prestored in the controller, the calculator 530, or the like.

Therefore, the above-described substrate processing apparatus 1000 may perform a substrate process monitoring method including calculating at least one parameter of a fluid discharged from the chamber 400 and determining at least one of a progress and end point of a process for the substrate S using the calculated parameter.

The process detecting unit 500 described above may calculate at least one parameter, for example, a dielectric constant of the fluid discharged from the chamber 400, and the controller compares the calculated dielectric constant of the fluid with a prestored dielectric constant to recognize a progress of the process when the drying process or the like is performed on the substrate S and a pressure change occurs.

The controller may determine that the process is completed when the calculated dielectric constant value reaches the dielectric constant reference value D_{end}.

According to the present disclosure having the above-described configuration, it may possible to check in real time whether the process proceeds smoothly by measuring a dielectric constant of the fluid discharged from a chamber to determine a progress of the process in real time.

According to the present disclosure, it may be possible to accurately detect an end point of a substrate process and quickly proceed with a subsequent process when a process for the substrate is completed, thereby reducing a processing time for the substrate and increasing processing efficiency.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A substrate processing apparatus comprising:
a chamber providing a processing space in which a process is performed on a substrate coated with a processing liquid or an organic solvent using a fluid in a supercritical state; and
a process detecting unit configured to calculate at least one parameter of the fluid discharged from the chamber and detect at least one of a progress of a process and an end point of the process for the substrate.

2. The substrate processing apparatus of claim 1, wherein the parameter includes a dielectric constant of the fluid.

3. The substrate processing apparatus of claim 2, wherein the process detecting unit determines that the process for the substrate is completed when a calculated value of the dielectric constant of the fluid reaches to a predetermined reference value or less.

4. The substrate processing apparatus of claim 3, wherein the reference value is determined using a predetermined margin in the dielectric constant in a state in which the fluid does not contain the processing liquid or an organic solvent.

5. The substrate processing apparatus of claim 2, wherein the process detecting unit calculates the dielectric constant of the fluid by measuring at least one of a capacitance, reflection coefficient, and resonance frequency of the fluid.

6. The substrate processing apparatus of claim 1, wherein the chamber includes at least one fluid discharge line from which the fluid in the chamber is discharged, and
the process detecting unit is provided in a section in which the fluid in the fluid discharge line is maintained in a supercritical state.

7. The substrate processing apparatus of claim 1, wherein the chamber includes at least one fluid discharge line from which the fluid in the chamber is discharged, a check valve provided on the fluid discharge line, and a pressure control valve provided behind the check valve in the fluid discharge line and configured to control a pressure inside the chamber, and
the process detecting unit is provided in front of the pressure control valve in the fluid discharge line.

8. The substrate processing apparatus of claim 7, wherein the process detecting unit is provided between the check valve and the pressure control valve in the fluid discharge line.

9. The substrate processing apparatus of claim 6, wherein the process detecting unit includes a sensor located in the fluid discharge line, and a calculator configured to calculate a dielectric constant of the fluid with a measurement value transmitted from the sensor, and
the sensor includes an external electrode providing a flow channel in which the fluid flows and an internal electrode provided inside the flow channel, and measures electric capacity of the fluid flowing between the external electrode and the internal electrode.

10. A substrate process monitoring method for detecting at least one of a progress and end point of the process for a substrate coated with a processing liquid or an organic solvent in a chamber using a fluid in a supercritical state, the method comprising:
calculating at least one parameter of the fluid discharged from the chamber; and
determining at least one of the progress of the process and the end point of the process for the substrate using the calculated parameter,
wherein the calculating of the parameter includes calculating a dielectric constant of the fluid discharged from the chamber.

11. The method of claim 10, wherein the calculating of the parameter includes calculating the dielectric constant of the fluid by measuring at least one of a capacitance, reflection coefficient, and resonance frequency of the fluid in a section in which the fluid discharged from the chamber is maintained in a supercritical state.

12. The method of claim 10, wherein the determining of at least one of the progress and end point of the process includes determining that the process for the substrate is completed when a calculated value of the dielectric constant of the fluid reaches to a predetermined reference value or less.

13. A process detecting unit for detecting at least one of a progress and end point of a process for a substrate coated with a processing liquid or an organic solvent in a chamber using a supercritical state, the process detecting unit comprising:
an external electrode providing a flow channel in which the fluid flows and an internal electrode provided inside the flow channel; and
calculator calculating a dielectric constant of the fluid discharged from the chamber and determines at least one of a progress of a process and an end point of the process for the substrate based on a calculated parameter of the dielectric constant of the fluid,
wherein the process detecting unit is provided in a section in which the fluid in a fluid discharge line is maintained in a supercritical state.

14. The process detecting unit of claim 13, wherein the process for the substrate is determined to be completed when the calculated value of the dielectric constant of the fluid reaches to a predetermined reference value or less.

15. The process detecting unit of claim 13, wherein the dielectric constant of the fluid is calculated by measuring at least one of a capacitance, reflection coefficient, and resonance frequency of the fluid.
